(19) United States
(12) Patent Application Publication
(10) Pub. No.: US 2025/0244667 A1
(43) Pub. Date: Jul. 31, 2025

(54) COMPOSITION

(71) Applicant: MERCK PATENT GMBH, DARMSTADT (DE)

(72) Inventors: ATSUKO NOYA, KAKEGAWA-SHI (JP); AKIRA YAMASAKI, KAKEGAWA-SHI (JP)

(21) Appl. No.: 19/064,544

(22) Filed: Feb. 26, 2025

Related U.S. Application Data
(63) Continuation of application No. PCT/EP2023/073076, filed on Aug. 23, 2023.

(30) Foreign Application Priority Data
Aug. 26, 2022 (EP) 22192492.1

(51) Int. Cl. G03F 7/027; G03F 7/16

(52) U.S. Cl. CPC G03F 7/0275; G03F 7/168

(57) ABSTRACT

The present invention relates to a composition containing an alkaline soluble polymer and a colorant.

### CROSS-REFERENCE TO RELATED APPLICATIONS

This application is a Continuation under 35 USC § 111(a) of International Patent Application No. PCT/EP2023/073076 filed Aug. 23, 2023, which claims priority to EP Application No. 22192492.1 filed Aug. 26, 2022, both of which are hereby incorporated herein by reference in their entirety.

### FIELD OF THE INVENTION

The present invention relates to a composition containing alkaline soluble polymer and a colorant. The present invention further relates to a method for fabricating a cured layer, a layer, a light converting device, an optical device, use of the device, use of the light converting device and method of fabricating an optical device.

### BACKGROUND ART

JP 2022-33154 A and JP 2021-113977 A (Toray) describes a polysiloxane based resin composition containing polysiloxane, white pigment, organic metal compound (working examples).

JP 2021-161401 A (Toray) indicates a polysiloxane based resin composition containing a photo radical generator, polysiloxane, and a polymer of (meth)acryl polymer or cardo type polymer as claimed in claim 1.

### SUMMARY OF THE INVENTION

However, the inventors newly have found that there are still one or more considerable problems for which improvement is desired, as listed below:
enabling development with a low-concentration alkaline developer, preferably in a shorter development time and/or achieving both reactivity and storage stability of the composition,
realizing high sensitivity of the composition lowering exposure energy and exposure time,
improving the structure of a patterned cured film (bank structure), especially, improving the bottom side structure of a patterned cured film,
realizing improved reflection and/or high optical density (OD) of the cured film, especially realizing improved reflection and/or high OD of the cured film having white and black pigments (grey colored bank).

The inventors aimed to solve one or more of the above-mentioned problems.

The present inventors have surprisingly found that one or more of the above described technical problems can be solved by the features as defined in the claims.

Namely, it was found a novel composition, preferably a photocurable composition, that preferably does not contain any polysiloxane, comprises:
i) an alkaline soluble polymer containing an ethylenic double bond; and
ii) a colorant.

In another aspect, the present invention also relates to a method for fabricating a cured layer comprising at least the following steps:
(Xi) providing the composition of the present invention onto a layer or onto a substrate to form a coated layer; and
(Xii) baking a coated layer to obtain a cured layer.

In another aspect, the present invention relates to a layer obtained or obtainable from the method of the present invention.

In another aspect, the present invention further relates to the color conversion device (100) obtainable or obtained from the method of the present invention.

In another aspect, the present invention also relates to a layer comprising at least;
i) a polymer (A) derived or derivable from an alkaline soluble polymer that includes an ethylenic double bond; and
ii) a colorant.

In another aspect, the present invention further relates to a light converting device comprising at least the layer of the present invention.

In another aspect, the present invention also relates to an optical device comprising at least the layer of the present invention or a light converting device of the present invention.

In another aspect, the present invention further relates to the use of the composition of the present invention, or the layer of the present invention in a fabrication process of a light converting device.

In another aspect, the present invention further relates to the use of the light converting device of the present invention in a fabrication process of an optical device.

In another aspect, the present invention further relates to a method of fabricating an optical device comprising: providing the light converting device of the present invention into an optical device.

Further advantages of the present invention will become evident from the following detailed description.

### DETAILED DESCRIPTION OF THE INVENTION

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-,” it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the descriptions such as “C_{x-y},” “Cₓ-C_{y}” and “Cₓ” mean the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when polymer has a plural types of repeating units, these repeating units copolymerize. These copolymerization are any of alternating copolymerization, random copolymerization, block copolymerization, graft copolymerization, or a mixture of any of these.

In the present specification, “%” represents mass % and “ratio” represents ratio by mass.

According to the present invention, the composition, preferably it is being of a photocurable composition, preferably said composition does not contain any polysiloxane, comprising at least, essentially consisting of or consisting of;
i) an alkaline soluble polymer containing an ethylenic double bond; and
ii) a colorant.

### —Alkali Soluble Polymer

The composition according to the present invention comprises an alkali-soluble polymer containing an ethylenic double bond.

Preferably the solid acid value of the alkaline polymer is in the range from 30 to 160 mgKOH/g, more preferably from 50 to 150 mg KOH/g, even more preferably from 60 to 80 mg KOH/g from the viewpoint of enabling development with a low-concentration alkaline developer, preferably in a shorter development time, and achieving both reactivity and storage stability. For examples, 2-Propenoic acid, 2-methyl-, polymer with 2-hydroxyethyl 2-methyl-2-propenoate, 2-isocyanatoethyl 2-propenoate and methyl 2-methyl-2-propenoate (C6 H10 O3·C6 H7 N O3·C5 H8 O2·C4 H6 O2)x (CAS Registry Number 1615232-03-05) can be used preferably to form the polymer.

In a preferable embodiment of the present invention, the weight-average molecular weight of said alkaline soluble polymer is in the range from 1,000 to 100,000, more preferably it is from 1,200 to 30,000, even more preferably it is from 3000 to 8000 from the view point of desirable viscosity, reactivity, developing ability, easy handling. Here, the weight average molecular weight is a weight average molecular weight in terms of polystyrene according to gel permeation chromatography.

Such alkali soluble polymer is available for example as described in JP 2016-69400 A (Natoko), ACA series from DAICELallnex co., such as (ACA) Z200M, (ACA) Z250, (ACA) Z251, (ACA) Z254F, (ACA) Z300, (ACA) Z320. Preferably said alkaline soluble polymer is polymer containing an acryloyl group. Thus, preferably said alkaline soluble polymer is a (meth)acrylate polymer, more preferably it is a methacrylate polymer, an acrylate polymer or a combination of thereof, even more preferably the polymer material is an acrylate polymer.

The alkali-soluble polymer used in the present invention can have a carboxyl group. By having a carboxyl group, the solubility of the alkali-soluble polymer in a low-concentration developer can be improved.

According to the present invention, the term “Alkali-soluble polymer” means a polymer soluble in 2.38% TMAH aqueous solution at 23.0±0.1° C.

### —(Meth)Acrylate Polymer

Here, the term “(meth)acrylate” is a general term for an acrylate and a methacrylate.

According to the present invention, when a low-concentration developer is used and/or low curing temperature is applied, it is preferable to use one or more of (meth)acrylate polymers.

The alkali-soluble polymer used in the present invention can be selected from generally used methacrylate polymer, an acrylate polymer or a combination of thereof, more preferably it is an acrylic polymer, for example, polyacrylic acid, polymethacrylic acid, polyalkyl acrylate, polyalkyl methacrylate, and the like. The acrylic polymer used in the present invention preferably comprises a repeating unit containing an acryloyl group, and also preferably further comprises a repeating unit containing a carboxyl group.

Although the repeating unit containing a carboxyl group is not particularly limited as long as it is a repeating unit containing a carboxyl group at its side chain, a repeating unit derived from an unsaturated carboxylic acid, an unsaturated carboxylic anhydride or a mixture thereof is preferable.

Further, it is preferable that the above-described polymer contains a repeating unit containing a hydroxyl group, which is derived from a hydroxyl group-containing unsaturated monomer.

Further, a (patterned) cured film is formed by applying the composition according to the present invention onto a substrate, imagewise exposure, and development. At this time, it is necessary that a difference in solubility occurs between the exposed area and the unexposed area, and the coating film in the unexposed area should have a certain or more solubility in a developer. For example, it is considered that a pattern can be formed by exposure and development if dissolution rate of the coating film after pre-baked, in a 2.38% tetramethylammonium hydroxide (hereinafter sometimes referred to as TMAH) aqueous solution (hereinafter sometimes referred to as alkali dissolution rate or ADR, which is described later in detail) is 50 Å/sec or more. However, since the required solubility varies depending on the film thickness of the cured film to be formed and the development conditions, the alkali-soluble polymer should be appropriately selected according to the development conditions. Although it varies depending on the type and addition amount of the photosensitizer or the silanol catalyst contained in the composition, for example, if the film thickness is 0.1 to 100 μm (1,000 to 1,000,000 Å), the dissolution rate in a 2.38% TMAH aqueous solution is preferably 50 to 20,000 Å/sec, and more preferably 100 to 10,000 Å/sec.

### —Thiol Containing Polyfunctional Chemical Compound

According to the present invention, in a preferable embodiment, said composition further comprises a thiol containing polyfunctional chemical compound. Preferably said thiol containing polyfunctional chemical compound contains a pentaerythritol structure.

In a more preferable embodiment, said thiol containing polyfunctional chemical compound is represented by following chemical formula (I^{x})

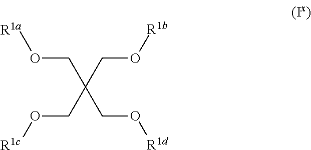

wherein
R^{1a}, R^{1b}, R^{1c} and R^{1d} are, independently of each other, selected from a hydrogen atom, alkyl chain having 1 to 10 carbon atoms, cyclo group having 3 to 10 carbon atoms cyclo-alkyl group having 4 to 10 carbon atoms, aryl group having 3 to 10 carbon atoms or an alkoxy group having 1 to 10 carbon atoms, where at least one H atom is replaced with SH group, where one or more non-adjacent CH₂ groups may be replaced by oxygen atom, C=O, C=S, C=Se, C═NH, SiH₂, SO, SO₂, OS, or CONH and where one or more H atoms may be replaced by D, F, Cl, Br, I, CN or NO₂, wherein at least one of R^{1a}, R^{1b}, R^{1c} and R^{1d} is not a hydrogen atom, preferably at least two of R^{1a}, R^{1b}, R^{1c} and R^{1d} are not a hydrogen atom, more preferably at least R^{1a}, R^{1b}, R^{1c} are not a hydrogen atom.

As the thiol containing polyfunctional chemical compound, publicly available one can be used. Examples of such thiol containing polyfunctional chemical compounds may include bifunctional thiols such as 1,4-bis(3-mercaptobutyryloxy) butane, 1,3,5-tris (2-(sulfanylbutanoyloxy) ethyl), tris-[(3-mercaptopropionyloxy)-ethyl-]-isocyanulate, trimethylolpropanetris (3-mercaptopropionate), dipentaerythritol hexakis (3-mercaptopropionate), trimethylolpropanetris (3-mercaptobutyrate), trimethylol-ethanthetris (3-mercaptobutylate) and other three-functional thiols such as 2-hydroxymethyl-2-methyl-1,3-propanediol Tris-(3-mercaptopropionate), Trimethylolpropane Tris(3-mercaptobutyrate), pentaerythritol tetrakis (3-sulfanylbutanoate) and the like include four-functional thiols. Among them, preferable one as the thiol containing polyfunctional chemical compound contains a pentaerythritol structure like Trimethylolpropane Tris(3-mercaptobutyrate) (Karenz MT-TPMB (Trademark)), Pentaerythritol tetrakis(3-mercaptobutyrate) (Karenz MT-PE-1 (Trademark)) from the view point of high sensitivity to lowering exposure energy and exposure time.

### —Polymerization Initiator

The composition according to the present invention may comprise a polymerization initiator. The polymerization initiator includes a polymerization initiator that generates an acid, a base or a radical by radiation, and a polymerization initiator that generates an acid, a base or a radical by heat.

Thus, in a preferable embodiment of the present invention, the composition further comprises a polymerization initiator. More preferably said polymerization initiator is selected from photo-radical initiators, photo-acid generators or a combination of photo-radical initiator and photo-acid generator.

From the view point of optimizing a bank structure, photo-acid generator is preferable. Since the composition contains a colorant, when the coated composition is irradiated with light to make a bank pattern after the composition is coated onto a surface of a substrate, the amount/strength of the irradiated light at the bottom side of the coated composition is smaller than the upper side of the coated composition. Meaning, the bottom side of the coated composition is not well photo-cured and it leads a distorted bank structure. It is believed that by adding photo-acid generator, this problem can be minimized or solved due to spreading a photo-generated acid in the composition.

Examples of the above photo acid-generator include diazomethane compounds, diphenyliodonium salts, triphenylsulfonium salts, sulfonium salts, ammonium salts, phosphonium salts and sulfonamide compounds. The structures of those photo acid-generators can be represented by the formula (A):

R⁺X⁻ (A).

Wherein the formula (A), R⁺ is hydrogen or an organic ion modified by carbon atoms or other hetero atoms provided that the organic ion is selected from the group consisting of alkyl groups, aryl groups, alkenyl groups, acyl groups and alkoxy groups. For example, R⁺ is diphenyliodonium ion or triphenylsulfonium ion.

Further, X⁻ is preferably a counter ion represented by any of the following formulas:

SbY₆⁻,

AsY₆⁻,

R^{a}ₚPY₆₋ₚ⁻,

R^{a}_{q}BY_{4-q}⁻,

R^{a}_{q}GaY_{4-q}⁻,

R^{a}SO₃⁻,

(R^{a}SO₂)₃C⁻,

(R^{a}SO₂)₂N⁻,

R^{a}COO⁻, and

SCN⁻
in which
Y is a halogen atom,
R^{a} is an alkyl group of 1 to 20 carbon atoms or an aryl group of 6 to 20 carbon atoms provided that each group is substituted with a substituent group selected from the group consisting of fluorine, nitro group and cyano group,
R^{b} is hydrogen or an alkyl group of 1 to 8 carbon atoms,
P is a number of 0 to 6, and
q is a number of 0 to 4.

Concrete examples of the counter ion include: BF₄⁻, (C₆F₅)₄B⁻, ((CF₃)₂C₆H₃)₄B⁻, PF₆⁻, (CF₃CF₂)₃PF₃⁻, SbF₆⁻, (C₆F₅)₄Ga⁻, ((CF₃)₂C₆H₃)₄Ga⁻, SCN⁻, (CF₃SO₂)₃C⁻, (CF₃SO₂)₂N⁻, formate ion, acetate ion, trifluoromethane-sulfonate ion, nonafluorobutanesulfonate ion, methane sulfonate ion, butanesulfonate ion, benzenesulfonate ion, p-toluenesulfonate ion, and sulfonate ion.

Among the photo acid-generators usable in the present invention, those generating sulfonic acids or boric acids are particularly preferred. Examples thereof include tricumyliodonium teterakis(pentafluoro phenyl)borate (PHOTOINITIATOR2074 [trademark], manufactured by Rhodorsil), diphenyliodonium tetra(perfluorophenyl)borate, and a compound having sulfonium ion and pentafluoroborate ion as the cation and anion moieties, respectively. Further, examples of the photo acid-generators also include triphenylsulfonium trifluoromethanesulfonate, triphenylsulfonium camphor sulfonate, triphenylsulfonium tetra(perfluorophenyl)borate, 4-acetoxyphenyldimethylsulfonium hexafluoroarsenate, 1-(4-n-butoxynaphthalene-1-yl)tetrahydrothiophenium trifluoromethanesulfonate, 1-(4,7-dibutoxy-1-naphthalenyl)tetrahydrothiophenium tri-fluoromethanesulfonate, diphenyliodonium trifluoromethanesulfonate, and diphenyliodonium hexafluoroarsenate. Furthermore, it is still also possible to adopt photo acid-generators represented by the following formulas:

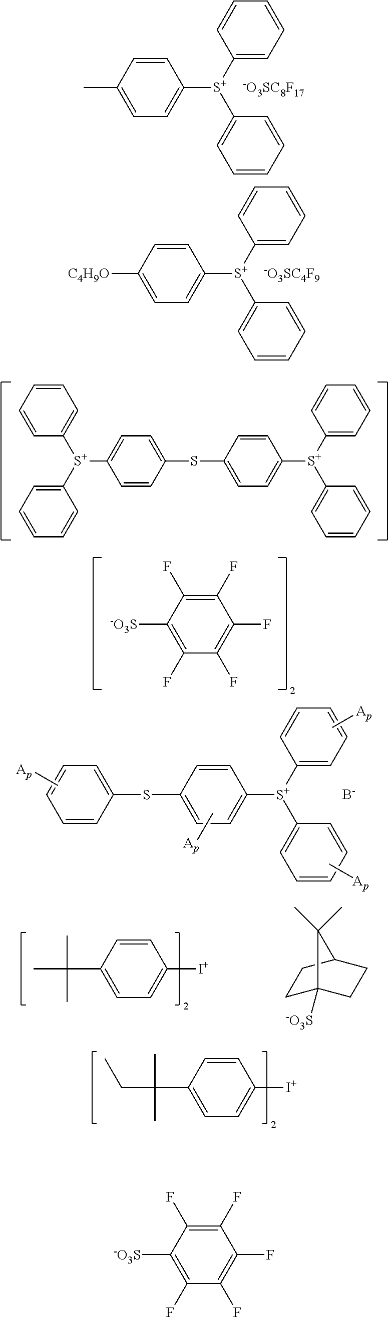

in which
each A is independently a substituent group selected from the group consisting of an alkyl group of 1 to 20 carbon atoms, an alkoxy group of 1 to 20 carbon atoms, an aryl group of 6 to 20 carbon atoms, an alkylcarbonyl group of 1 to 20 carbon atoms, an arylcarbonyl group of 6 to 20 carbon atoms, hydroxyl group, and amino group;
each p is independently an integer of 0 to 5; and
B⁻ is a fluorinated alkylsulfonate group, a fluorinated arylsulfonate group, a fluorinated alkylborate group, an alkylsulfonate group or an arylsulfonate group.

It is also possible to use photo acid-generators in which the cations and anions in the above formulas have exchanged each other or combined with various other cations and anions described above. For example, any one of the sulfonium ions represented by the above formulas can be combined with tetra(perfluorophenyl)borate ion, and also any one of the iodonium ions represented by the above formulas can be combined with tetra(per-fluorophenyl)borate ion. Those can be still also employed as the photo acid-generators.

In the present invention, the photo radical generator is more preferable in terms of process shortening and cost since the reaction is initiated immediately after the radiation irradiation and the reheating process performed after the radiation irradiation and before the developing process can be omitted.

The photo radical generator can improve the resolution by strengthening the pattern shape or increasing the contrast of development. The photo radical generator used in the present invention is a photo radical generator that emits a radical when irradiated with radiation. Here, examples of the radiation include visible light, ultraviolet light, infrared light, X-ray, electron beam, α-ray, and γ-ray.

The addition amount of the photo radical generator is preferably 0.001 to 50 mass %, more preferably 0.01 to 30 mass %, based on the total mass of the alkali-soluble polymer, though the optimal amount thereof depends on the type and amount of active substance generated by decomposition of the photo radical generator, the required photosensitivity, and the required dissolution contrast between the exposed area and unexposed area. If the addition amount is less than 0.001 mass %, the dissolution contrast between the exposed area and unexposed portion is too low, and the addition effect is not sometimes exhibited. On the other hand, when the addition amount of the photo radical generator is more than 50 mass %, colorless transparency of the coated film sometimes decreases, because it sometimes occurs that cracks are generated in the coated film to be formed and coloring due to decomposition of the photo radical generator becomes remarkable. Further, when the addition amount becomes large, thermal decomposition of the photo radical generator causes deterioration of the electrical insulation of the cured product and release of gas, which sometimes become a problem in subsequent processes. Further, the resistance of the coated film to a photoresist stripper containing monoethanolamine or the like as a main component sometimes deteriorates.

Examples of the photo radical generator include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferred, and 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenyl phosphine oxide, bis(2,4,6-trimethylbenzoyl)-phenyl-phosphine oxide, 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime), Bis(2,4-cyclopentadienyl)bis[2,6-difluoro-3-(1 H-pyrrole-1-yl)phenyl]titanium(IV) and the like are included.

### —Chemical Compound Containing at Least Two (Meth)Acryloyloxy Groups

In a preferable embodiment of the present invention, the composition further comprises a chemical compound containing at least two (meth)acryloyloxy groups.

Preferably said at least two(meth)acryloyloxy groups are two or more acryloyloxy groups, methacryloyloxy groups or a combination of these, preferably the total amount of the chemical compound containing said at least two (meth)acryloyloxy groups based on the total amount of the alkaline soluble polymer is in the range from 5 wt. % to 1,000 wt. %, more preferably from 10 wt. % to 500 wt. %, even more preferably it is from 15 wt. % to 300 wt. % from the viewpoint of compatibility with resin., preferably said chemical compound is a monomer having the molecular weight 2000 or less, more preferably in the range from 2000 to 50, even more preferably from 1000 to 100. Preferably it is relatively smaller than the alkali-soluble polymer from the viewpoint of reactivity.

Here, the term “(meth)acryloyloxy group” is a general term for the acryloyloxy group and the methacryloyloxy group. This compound is a compound that can form a crosslinked structure by reacting with the alkali-soluble polymer. Here, in order to form a crosslinked structure, a compound containing two or more acryloyloxy groups or methacryloyloxy groups, which are reactive groups, is needed, and in order to form a higher-order crosslinked structure, it preferably contains three or more acryloyloxy groups or methacryloyloxy groups.

Further, the (meth)acryloyloxy group-containing compounds can be used alone or in combination of two or more.

Preferably said chemical compound containing at least two (meth)acryloyloxy groups, is a poly acrylate monomer having at least three (meth)acryloyloxy groups, more preferably it is a poly acrylate monomer selected from one or more member of the group consisting of a poly acrylate monomer having three (meth)acryloyloxy groups, a poly acrylate monomer having four (meth)acryloyloxy groups, a poly acrylate monomer having five (meth)acryloyloxy groups, a poly acrylate monomer having six (meth)acryloyloxy groups, even more preferably it is a poly acrylate monomer having five (meth)acryloyloxy groups, a poly acrylate monomer having six (meth)acryloyloxy groups or a mixture of thereof,

preferably said poly acrylate monomer having three (meth)acryloyloxy groups is selected from one or more member of the group consisting of trimethylolpropane triacrylate, trimethylolpropaneethoxy triacrylate, trimethylolpropanepropoxy triacrylate, glycerinpropoxy triacrylate, pentaerythritol triacrylates;

preferably said poly acrylate monomer having four (meth)acryloyloxy groups is selected from one or more member of the group consisting of pentaerythritol tetraacrylates, ditrimethylolpropane tetraacrylate, pentaerythritolehoxy tetraacrylates;

preferably said poly acrylate monomer having five (meth)acryloyloxy groups is dipentaerythritol hexaacrylates, preferably said poly acrylate monomer having six (meth)acryloyloxy groups is dipentaerythritol pentaacrylate, the most preferably said chemical compound is dipentaerythritol hexaacrylates, dipentaerythritol pentaacrylate or a mixture of thereof.

### —Surfactant

Further, the composition according to the present invention can optionally comprise a surfactant. Preferably it is a nonionic surfactant, preferably said nonionic surfactant is a hydrocarbon based nonionic surfactant, fluorine-based nonionic surfactant, such as Fluorad (trade name, 3M Japan Limited), Megafac (trade name, DIC Corporation), Surflon (trade name, AGC Inc.), organosilicon based nonionic surfactant, such as KP341 (trade name, Shin-Etsu Chemical Co., Ltd.) or a combination of these, more preferably said hydrocarbon based nonionic surfactant is selected from one or more members the group consisting of polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycol such as 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-di-methyl-3-hexyne-2,5-diol, 2,5-di-methyl-2,5-hexanediol; polyethoxylate of acetylene alcohol; acetylene glycol derivatives, such as polyethoxylate of acetylene glycol; preferably fluorine-based nonionic surfactant is selected from one or more of fluorine-containing surfactants; preferably said hydrocarbon based nonionic surfactant is selected from organosiloxane surfactants, preferably the surfactant is a fluorine-based nonionic surfactant. Especially, Megafac RS series (trade name, DIC Corporation) is the most suitable one for the present invention from the view point of realizing improved hydrophobic bank surface, and/or realizing improved oil-repellent bank surface (especially realizing an oil-repellent surface of the top part of a bank after fabrication of it).

Preferably, the total amount of the surfactant is in the range from 0.001 to 5 wt. %, more preferably from 0.01 to 4 wt. %, even more preferably from 0.05 to 3 wt. %, furthermore preferably from 0.1 to 1 wt. % based on the total amount of the total solid contents of the composition.

The surfactant is added for the purpose of improving coating properties, developability, realizing improved hydrophobic bank surface, and/or realizing improved oil-repellent bank surface.

### —Colorant

According to the present invention, the composition comprises a colorant, preferably the total amount of said colorant is 3 to 80 wt. %, preferably 5 to 50 wt. % based on the total amount of the solid contents of the composition.

Preferably said colorant is a 1^{st} colorant selected from an organic colorant and/or an inorganic colorant, more preferably it is a black colorant selected from an organic black pigment and/or inorganic black pigment or a white colorant selected from an organic white pigment and/or inorganic white pigment, furthermore preferably it is a black colorant selected from an organic black pigment and/or inorganic black pigment, even more preferably it is a inorganic black pigment, particularly preferably said inorganic black pigment is zirconium nitride or a tinatnina oxide, which may be coated by a polymer and/or inorganic layer.

As the colorant used in the present invention (preferably black colorant), either an inorganic pigment or an organic pigment, or a combination of two or more pigments can be used as long as it satisfies the required absorbance.

When an organic type black colorant is used in the bank, it is preferable to combine two or more organic pigments to obtain a black pigment. For examples, by mixing respective colors of red, green and blue organic pigments, a black color pigment can be obtained.

The colorant used in the present invention can be used in combination with a dispersant. As the dispersant, an organic compound-based dispersant such as a polymer dispersant described, for example, in JP-A 2004-292672 can be used.

In a preferable embodiment of the present invention, the composition further comprises another colorant different from the 1^{st} colorant.

preferably said another colorant is a 2^{nd} colorant selected from an organic colorant and/or an inorganic colorant, more preferably it is a black colorant selected from an organic black pigment and/or inorganic black pigment or a white colorant selected from an organic white pigment and/or inorganic white pigment, even more preferably it is a white colorant selected from an organic white pigment and/or inorganic white pigment, furthermore preferably it is an inorganic white colorant.

Thus, in a further preferable embodiment of the present invention, the composition comprises the 1^{st} colorant and the 2^{nd} colorant, wherein the 1^{st} colorant is a black pigment and the 2^{nd} colorant is a white pigment to realize grey colored composition and grey colored patterned bank.

### —Solvent

In a preferred embodiment of the present invention, the composition further comprises a solvent.

The type solvent is not particularly limited and publicly available solvents can be used as long as it can uniformly dissolve or disperse the above-described alkali-soluble polymer, the polymerization initiator and a chemical compound containing at least two (meth)acryloyloxy groups.

Preferably said solvent is selected from one or more of the members of the group consisting of ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates such as PGMEA, propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate, methyl 3-methoxypropionate; and cyclic esters, such as γ-butyrolactone, more preferably said solvent is a combination of propylene glycol alkyl ether acetates or esters, and cyclic esters, such as γ-butyrolactone, preferably the total amount of said solvent based on the total amount of the composition is in the range from 1 wt. % to 99 wt. %, preferably from 5 wt. % to 90 wt. %, even more preferably from 10 wt. % to 80 wt. %, furthermore preferably from 20 wt. % to 70 wt. %.

### —Other Additives

The composition according to the present invention can optionally comprise other additives. As such additives, a developer dissolution accelerator, a scum remover, an adhesion enhancer, a polymerization inhibitor, an antifoaming agent, a surfactant, a photosensitizing enhancing agent, a crosslinking agent, a curing agent can be added.

Thus, according to the present invention, preferably the composition further comprises at least one additive selected from one or more members of the group consisting of a developer dissolution accelerator, a scum remover, an adhesion enhancer, a polymerization inhibitor, an antifoaming agent, a surfactant, a photosensitizing enhancing agent, a crosslinking agent, and/or a curing agent.

The developer dissolution accelerator or scum remover has a function of adjusting the solubility of the formed coated film in the developer and preventing scum from remaining on the substrate after development. As such an additive, crown ether can be used. The crown ether having the simplest structure is represented by the general formula (—CH₂—CH₂—O—)ₙ. Preferred in the present invention are those in which n is 4 to 7. When x is set to be the total number of atoms constituting the ring and y is set to be the number of oxygen atoms contained therein, the crown ether is sometimes called x-crown-y-ethers. In the present invention, preferred is selected from the group consisting of crown ethers, wherein x=12, 15, 18 or 21, and y=x/3, and their benzo condensates and cyclohexyl condensates. Specific examples of more preferred crown ethers include 21-crown-7-ether, 18-crown-6-ether, 15-crown-5-ether, 12-crown-4-ether, dibenzo-21-crown-7-ether, dibenzo-18-crown-6-ether, dibenzo-15-crown-5-ether, dibenzo-12-crown-4-ether, dicyclohexyl-21-crown-7-ether, dicyclohexyl-18-crown-6-ether, dicyclo-hexyl-15-crown-5-ether, and dicyclohexyl-12-crown-4-ether. In the present invention, among them, most preferred is selected from 18-crown-6-ether and 15-crown-5-ether. The content thereof is preferably 0.05 to 15 mass %, more preferably 0.1 to 10 mass %, based on the total mass of the alkali-soluble polymer.

The adhesion enhancer has an effect of preventing a pattern from peeling off due to stress applied after baking when a cured film is formed using the composition according to the present invention. As the adhesion enhancer, imidazoles, silane coupling agents, and the like are preferred. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferable, and 2-hydroxybenzimidazole, benzimidazole, 2-hydroxyimidazole and imidazole are particularly preferably used.

As the silane coupling agent, known ones are suitably used, and examples thereof include epoxy silane coupling agents, amino silane coupling agents, mercapto silane coupling agents, and the like. Specifically, 3-glycidoxypropyltrimethoxysilane, 3-glycidoxypropyl-triethoxysilane, N-2-(aminoethyl)-3-aminopropyltri-methoxysilane, N-2-(aminoethyl)-3-aminopropyltri-ethoxysilane, 3-aminopropyltrimethoxysilane, 3-amino-propyltriethoxysilane, 3-ureidopropyltriethoxysilane, 3-chloropropyltriethoxysilane, 3-mercaptopropyltri-methoxysilane, 3-isocyanatopropyltriethoxysilane, and the like are preferred. These can be used alone or in combination of two or more, and the addition amount thereof is preferably 0.05 to 15 mass % based on the total mass of the alkali-soluble polymer.

Further, as the silane coupling agent, a silane compound and siloxane compound having an acid group, or the like can be used. Examples of the acid group include a carboxyl group, an acid anhydride group, a phenolic hydroxyl group, and the like. When it contains a monobasic acid group such as a carboxyl group or a phenolic hydroxyl group, it is preferred that a single silicon-containing compound has a plurality of acid groups.

Exemplified embodiments of such a silane coupling agent include a compound represented by the formula (C):

XₙSi(OR^{C3})₄₋ₙ (C)

or polymer obtained using it as a repeating unit. At this time, a plurality of repeating units having different X or R^{C3} can be used in combination.

In the formula, R^{C3} includes a hydrocarbon group, for example, an alkyl group such as a methyl group, an ethyl group, an n-propyl group, an isopropyl group, and an n-butyl group. In the general formula (C), a plurality of R^{C3} are included, and each R^{C3} can be identical or different.

As X, those having an acid group such as phosphonium, borate, carboxyl, phenol, peroxide, nitro, cyano, sulfo, and alcohol group are included, and those in which these acid groups are protected by acetyl, aryl, amyl, benzyl, methoxymethyl, mesyl, tolyl, trimethoxysilyl, triethoxysilyl, triisopropylsilyl or trityl group, and an acid anhydride group are included.

Among them, a compound having a methyl group as R^{C3} and a carboxylic acid anhydride group as X, such as an acid anhydride group-containing silicone, is preferable. More specifically, a compound represented by the following formula (X-12-967C (trade name, Shin-Etsu Chemical Co., Ltd.)) or polymer containing a structure corresponding thereto in its terminal or side chain of a silicon-containing polymer such as silicone is preferred.

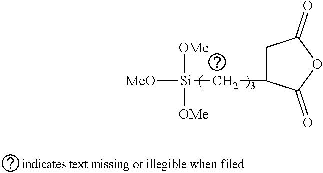

Further, a compound in which thiol, phosphonium, borate, carboxyl, phenol, peroxide, nitro, cyano, and an acid group such as sulfo group is provided at the terminal of dimethyl silicone is also preferable. As such a compound, compounds represented by the following formulae (X-22-2290AS and X-22-1821 (trade name in every case, Shin-Etsu Chemical Co., Ltd.)) are

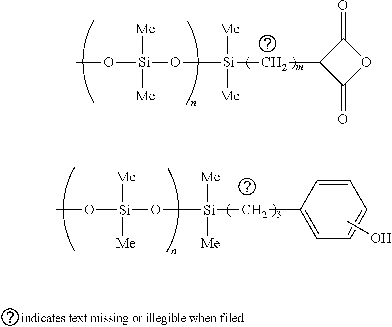

included.

When the silane coupling agent has a silicone structure, if the molecular weight is too large, the compatibility with polysiloxane contained in the composition becomes poor, so that there is a possibility that there is an adverse effect such that the solubility in the developer does not improve, the reactive group remains in the film, and the chemical resistance that can withstand the subsequent process cannot be maintained. For this reason, the mass average molecular weight of the silane coupling agent is preferably 5,000 or less, and more preferably 4,000 or less. The content of the silane coupling agent is preferably 0.01 to 15 mass % based on the total mass of the alkali-soluble polymer.

As the polymerization inhibitor, an ultraviolet absorber as well as nitrone, nitroxide radical, hydroquinone, catechol, phenothiazine, phenoxazine, hindered amine and derivatives thereof can be added. Among them, methylhydroquinone, catechol, 4-t-butylcatechol, 3-methoxycatechol, phenothiazine, chlorpromazine, phenoxazine, TINUVIN 144, 292 and 5100 (BASF) as the hindered amine, and TINUVIN 326, 328, 384-2, 400 and 477 (BASF) as the ultraviolet absorber are preferred. These can be used alone or in combination of two or more, and the content thereof is preferably 0.01 to 20 mass % based on the total mass of the alkali-soluble polymer.

As the antifoaming agent, alcohols (C₁₋₁₈), higher fatty acids such as oleic acid and stearic acid, higher fatty acid esters such as glycerin monolaurate, polyethers such as polyethylene glycols (PEG) (Mn: 200 to 10,000) and polypropylene glycols (PPG) (Mn: 200 to 10,000), silicone compounds such as dimethyl silicone oil, alkyl-modified silicone oil and fluorosilicone oil, and organosiloxane-based surfactants described in detail below are included. These can be used alone or in combination of a plurality of these, and the content thereof is preferably 0.1 to 3 mass % based on the total mass of the alkali-soluble polymer.

### —Photosensitizing Enhancing Agent

A photosensitizing enhancing agent can be optionally added to the bank composition according to the present invention. The photosensitizing enhancing agent preferably used in the composition according to the present invention includes coumarin, ketocoumarin and their derivatives, thiopyrylium salts, acetophenones, and the like, and specifically, p-bis(o-methylstyryl) benzene, 7-dimethylamino-4-methylquinolone-2,7-amino-4-methylcoumarin, 4,6-di-methyl-7-ethylaminocoumarin, 2-(p-dimethylamino-styryl)-pyridylmethyl-iodide, 7-diethylaminocoumarin, 7-diethylamino-4-methyl-coumarin, 2,3,5,6-1H,4H-tetrahydro-8-methyl-quinolizino-<9,9a,1-gh> coumarin, 7-diethylamino-4-trifluoromethylcoumarin, 7-dimethyl-amino-4-trifluoro-methylcoumarin, 7-amino-4-trifluoro-methylcoumarin, 2,3,5,6-1H,4H-tetrahydroquinolizino-<9,9a,1-gh> coumarin, 7-ethylamino-6-methyl-4-trifluoromethylcoumarin, 7-ethylamino-4-trifluoro-methylcoumarin, 2,3,5,6-1H,4H-tetrahydro-9-carbo-ethoxyquinolizino-<9,9a,1-gh> coumarin, 3-(2′-N-methylbenzimidazolyl)-7-N,N-diethylaminocoumarin, N-methyl-4-trifluoro-methylpiperidino-<3,2-g> coumarin, 2-(p-dimethylaminostyryl)-benzothiazolylethyl iodide, 3-(2′-benzimidazolyl)-7-N,N-diethylaminocoumarin, 3-(2′-benzothiazolyl)-7-N,N-diethylaminocoumarin, and sensitizing dyes such as pyrylium salts and thiopyrylium salts represented by the following chemical formula. By the addition of the sensitizing dye, patterning using an inexpensive light source such as a high-pressure mercury lamp (360 to 430 nm) becomes possible. The content thereof is preferably 0.05 to 15 mass %, more preferably 0.1 to 10 mass %, based on the total mass of the alkali-soluble polymer.

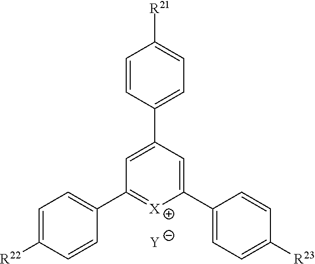

| X | R²¹ | R²² | R²³ | Y |
|---|---|---|---|---|
| S | OC₄H [symbol] | H | H | BF₄ |
| S | OC₄H [symbol] | OCH₃ | OCH₃ | BF₄ |
| 5 | H | OCH₃ | OCH₃ | BF₄ |
| S | N(CH₃)₂ | H | R | ClO₂ |
| O | OC₄H [symbol] | H | H | SbF [symbol] |

[symbol]

indicates data missing or illegible when filed

Further, as the photosensitizing enhancing agent, an anthracene skeleton-containing compound can be also used. Specifically, a compound represented by the following formula is included.

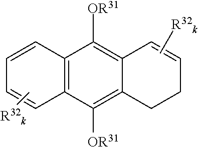

wherein, R³¹ each independently represents a substituent selected from the group consisting of an alkyl group, an aralkyl group, an allyl group, a hydroxyalkyl group, an alkoxyalkyl group, a glycidyl group, and a halogenated alkyl group,

R³² each independently represents a substituent selected from the group consisting of a hydrogen atom, an alkyl group, an alkoxy group, a halogen atom, a nitro group, a sulfonic acid group, a hydroxyl group, an amino group, and a carboalkoxy group, and

k is each independently selected from 0 and an integer of 1 to 4.

When such a photosensitizing enhancing agent having an anthracene skeleton is used, its content is preferably 0.01 to 5 mass % based on the total mass of the alkali-soluble polymer.

In another aspect, the present invention further relates to a method for fabricating a cured layer comprising at least the following steps;
(Xi) providing the composition of the present invention onto a layer or onto a substrate to form a coated layer; and
(Xii) baking a coated layer to obtain a cured layer.

Preferably the method further comprises one or more of the following steps after step (Xi) and before the step (Xii):
(Xiii) Applying a pre-baking (heat treatment) of the coating layer in order to dry the coated layer and reduce the residual amount of the solvent in the coated layer. Preferably said pre-baking process is carried out at a temperature of generally 50 to 150° C., preferably 90 to 120° C., in the case of a hot plate, for 10 to 300 seconds, preferably 30 to 120 seconds and in the case of a clean oven, for 1 to 30 minutes;
(Xiv) irradiating the coated layer with light (applying light irradiation), preferably with light having peak maximum wavelength in the range from 360 to 430 nm, preferably a patterning mask is used when light irradiation is carried out;
(Xv) applying post exposure baking process; and/or
(Xvi) applying developing process to form a patterned cured layer.

### —Method for Fabricating a Cured Layer (Preferably Bank Fabrication Process)

### Step (Xi): Application Process

First, the above-described composition is applied onto a substrate.

Formation of the coating film of the composition in the present invention can be carried out by any method conventionally known as a method for applying a photosensitive composition. Specifically, it can be freely selected from dip coating, roll coating, bar coating, brush coating, spray coating, doctor coating, flow coating, spin coating, slit coating, and the like. Further, as the substrate on which the composition is applied, a suitable substrate such as a silicon substrate, a glass substrate, a resin film, and the like can be used. Various semiconductor devices and the like can be formed on these substrates as needed. When the substrate is a film, gravure coating can also be utilized. If desired, a drying process can be additionally provided after applying the film. Further, if necessary, the applying process can be repeated once or twice or more to make the film thickness of the coating film to be formed as desired.

### Step (Xiii): Pre-Baking Process

After forming the coating film of the composition by applying the composition, it is preferable to carry out pre-baking (heat treatment) of the coating film in order to dry the coating film and reduce the residual amount of the solvent in the coating film. The pre-baking process can be carried out at a temperature of generally 50 to 150° C., preferably 90 to 120° C., in the case of a hot plate, for 10 to 300 seconds, preferably 30 to 120 seconds and in the case of a clean oven, for 1 to 30 minutes.

### Step (Xiv): Exposure Process

After forming a coating film, the coating film surface is then irradiated with light. As the light source to be used for the light irradiation, any one conventionally used for a pattern forming method can be used. As such a light source, a high-pressure mercury lamp, a low-pressure mercury lamp, a lamp such as metal halide and xenon, a laser diode, an LED and the like can be included. As the irradiation light, ultraviolet ray such as g-line, h-line and i-line is usually used. Except ultrafine processing for semiconductors or the like, it is general to use light of 360 to 430 nm (high-pressure mercury lamp) for patterning of several μm to several dozens of μm. The energy of the irradiation light is generally 5 to 2,000 mJ/cm², preferably 10 to 1,000 mJ/cm², although it depends on the light source and the film thickness of the coating film. If the irradiation light energy is lower than 5 mJ/cm², sufficient resolution cannot be obtained in some cases. On the other hand, when the irradiation light energy is higher than 2,000 mJ/cm², the exposure becomes excess and occurrence of halation is sometimes brought.

In order to irradiate light in a pattern shape, a general photomask can be used. Such a photomask can be freely selected from well-known ones. The environment at the time of irradiation is not particularly limited and can generally be set as an ambient atmosphere (in the air) or nitrogen atmosphere. Further, in the case of forming a film on the entire surface of the substrate, light irradiation can be performed over the entire surface of the substrate. In the present invention, the pattern film also includes such a case where a film is formed on the entire surface of the substrate.

### Step (Xv): Post Exposure Baking Process

After the exposure, to promote the reaction between the polymer in the film by the polymerization initiator, post exposure baking can be performed as necessary. Different from the heating process (6) to be described later, this heating treatment is performed not to completely cure the coating film but to leave only a desired pattern on the substrate after development and to make other areas capable of being removed by development. Therefore, it is not essential in the present invention.

When the post exposure baking is performed, a hot plate, an oven, a furnace, and the like can be used. The heating temperature should not be excessively high because it is not desirable for the acid, base or radical in the exposed area, which is generated by light irradiation, to diffuse to the unexposed area. From such a viewpoint, the range of the heating temperature after exposure is preferably 40 to 150° C., and more preferably 60 to 120° C. Stepwise heating can be applied as needed to control the curing rate of the composition. Further, the atmosphere during the heating is not particularly limited and can be selected from in an inert gas such as nitrogen, under a vacuum, under a reduced pressure, in an oxygen gas, and the like, for the purpose of controlling the curing rate of the composition. Further, the heating time is preferably above a certain level in order to maintain higher the uniformity of temperature history in the wafer surface and is preferably not excessively long in order to suppress diffusion of the generated acid, base or radical. From such a viewpoint, the heating time is preferably 20 seconds to 500 seconds, and more preferably 40 seconds to 300 seconds.

### Step (Xvi): Developing Process

After post-exposure heating is optionally performed after exposure, the coating film is developed. As the developer to be used at the time of development, any developer conventionally used for developing a photosensitive composition can be used. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), a sodium carbonate aqueous solution, ammonia, alkylamine, alkanolamine and heterocyclic amine, and a particularly preferable alkali developer is a tetramethylammonium hydroxide aqueous solution, a potassium hydroxide aqueous solution, a sodium hydroxide aqueous solution, or a sodium carbonate aqueous solution. In this alkali developer, a water-soluble organic solvent such as methanol and ethanol, or a surfactant can be further contained, if necessary. In the present invention, the development can be performed using a developer having a lower concentration than a 2.38 mass % TMAH developer that is usually used as a developer. Examples of such a developer include a 0.05 to 1.5 mass % TMAH aqueous solution, a 0.1 to 2.5 mass % sodium carbonate aqueous solution, and a 0.01 to 1.5 mass % potassium hydroxide aqueous solution. The developing time is usually 10 to 300 seconds, preferably 30 to 180 seconds. The developing method can also be freely selected from conventionally known methods. Specifically, methods such as dipping in a developer (dip), paddle, shower, slit, cap coat, spray, and the like can be included. After the development with a developer, by which a pattern can be obtained, it is preferable that rinsing with water is carried out.

### Step (Xii): Heating Process

After development, the obtained pattern film is cured by heating. As the heating apparatus used for the heating process, the same one as used for the above-described post-exposure heating can be used. The heating temperature in this heating process is not particularly limited as long as it is a temperature at which curing of the coating film can be performed, and it can be freely determined.

The composition according to the invention is capable of being cured at relatively low temperature. Specifically, it is preferable to cure by heating at 350° C. or lower, and in order to maintain a high remaining film ratio after curing, the curing temperature is more preferably 300° C. or lower, and particularly preferably 250° C. or lower.

On the other hand, in order to accelerate the curing reaction and obtain a sufficiently cured film, the curing temperature is preferably 70° C. or higher, more preferably 100° C. or higher. According to the present invention, low curing temperature such as around 100° C. is more preferable. Further, the heating time is not particularly limited and is generally 10 minutes to 24 hours, and preferably 30 minutes to 3 hours. In addition, this heating time is a time from when the temperature of the pattern film reaches a desired heating temperature. Usually, it takes about several minutes to several hours for the pattern film to reach a desired temperature from the temperature before heating.

In another aspect, the present invention further relates to a layer obtained or obtainable from the method of the present invention.

In another aspect, the present invention further relates to a layer comprising at least, essentially consisting of or consisting of;
i) a polymer (A) derived or derivable from an alkaline soluble polymer containing an ethylenic double bond;
preferably the solid acid value of the alkaline polymer is in the range from 30 to 160 mgKOH/g, more preferably from 50 to 150 mg KOH/g, even more preferably from 60 to 80 mg KOH/g,
preferably the weight-average molecular weight of said alkaline soluble polymer is in the range from 1,000 to 100,000, more preferably it is from 1,200 to 30,000, even more preferably it is from 3000 to 8000,
preferably said alkaline soluble polymer is selected from (meth)acrylate polymer, more preferably it is a methacrylate polymer, an acrylate polymer or a combination of thereof, even more preferably the polymer material is an acrylate polymer; and
ii) a colorant.

Preferably said layer is a patterned layer.

Preferably said colorant is a 1^{st} colorant selected from an organic colorant and/or an inorganic colorant, more preferably it is a black colorant selected from an organic black pigment and/or inorganic black pigment or a white colorant selected from an organic white pigment and/or inorganic white pigment, furthermore preferably it is a black colorant selected from an organic black pigment and/or inorganic black pigment, even more preferably it is a inorganic black pigment, particularly preferably said inorganic black pigment is zirconium nitride or a tinatnina oxide, which may be coated by a polymer and/or inorganic layer.

In a preferable embodiment of the present invention, the Optical Density (OD) value of the layer at 10 μm layer thickness at light wavelength 460 nm is in the range from 1.0 to 3.0, the OD value of the layer at 10 μm layer thickness at light wavelength 540 nm is in the range from 1.0 to 3.0, and/or the OD value of the layer at 10 μm layer thickness at light wavelength 630 nm is in the range from 1.0 to 3.0.

In a preferable embodiment of the present invention, the reflection of the layer at 10 μm layer thickness at light wavelength 460 nm is in the range from 30 to 90%, at light wavelength 540 nm is in the range from 30 to 90% and/or at light wavelength 630 nm is in the range from 30 to 90%.

In another aspect, the present invention further relates to a light converting device comprising at least the layer of the present invention. Preferably said light converting device further comprises a substrate. Preferably said light converting device is a color filter, a pixelated color conversion device.

In another aspect, the present invention further relates to an optical device comprising at least the layer of the present invention or a light converting device of the present invention. Preferably said optical device is a display device, more preferably said display device is selected from the group consisting of OLED, LCD, LED and μLED.

In another aspect, the present invention further relates to use of the composition of the present invention, or the layer of the present invention in a fabrication process of a light converting device

In another aspect, the present invention further relates to use of the light converting device of the present invention in a fabrication process of an optical device.

In another aspect, the present invention further relates to a method of fabricating an optical device comprising at least; providing the light converting device of the present invention into an optical device.

### PREFERABLE EMBODIMENTS

1. A composition, preferably it is being of a photocurable composition, preferably said composition does not contain any polysiloxane, comprising at least, mainly consisting of or consisting of;
i) an alkaline soluble polymer containing an ethylenic double bond;
preferably the solid acid value of the alkaline polymer is in the range from 30 to 160 mgKOH/g, more preferably from 50 to 150 mg KOH/g, even more preferably from 60 to 80 mg KOH/g,
preferably the weight-average molecular weight of said alkaline soluble polymer is in the range from 1,000 to 100,000, more preferably it is from 1,200 to 30,000, even more preferably it is from 3000 to 8000,
preferably said alkaline soluble polymer is a (meth)acrylate polymer, more preferably it is a methacrylate polymer, an acrylate polymer or a combination of thereof, even more preferably the polymer material is an acrylate polymer; and
ii) a colorant.
preferably said colorant is a 1^{st} colorant selected from an organic colorant and/or an inorganic colorant, more preferably it is a black colorant selected from an organic black pigment and/or inorganic black pigment or a white colorant selected from an organic white pigment and/or inorganic white pigment, furthermore preferably it is a black colorant selected from an organic black pigment and/or inorganic black pigment, even more preferably it is a inorganic black pigment, particularly preferably said inorganic black pigment is zirconium nitride or a tinatnina oxide, which may be coated by a polymer and/or inorganic layer.

2. The composition of embodiment 1, further comprises a thiol containing polyfunctional chemical compound. Preferably said thiol containing polyfunctional chemical compound contains a pentaerythritol structure.

More preferably said thiol containing polyfunctional chemical compound is represented by following chemical formula (I^{x})

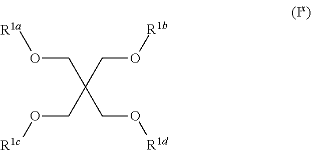

wherein
R^{1a}, R^{1b}, R^{1c} and R^{1d} are, independently of each other, selected from a hydrogen atom, alkyl chain having 1 to 10 carbon atoms, cyclo group having 3 to 10 carbon atoms cyclo-alkyl group having 4 to 10 carbon atoms, aryl group having 3 to 10 carbon atoms or an alkoxy group having 1 to 10 carbon atoms, where at least one H atom is replaced with SH group, where one or more non-adjacent CH₂ groups may be replaced by oxygen atom, C=O, C=S, C=Se, C═NH, SiH₂, SO, SO₂, OS, or CONH and where one or more H atoms may be replaced by D, F, Cl, Br, I, CN or NO₂, wherein at least one of R^{1a}, R^{1b}, R^{1c} and R^{1d} is not a hydrogen atom, preferably at least two of R^{1a}, R^{1b}, R^{1c} and R^{1d} are not a hydrogen atom, more preferably at least R^{1a}, R^{1b}, R^{1c} are not a hydrogen atom.

3. The composition of embodiment 1 or 2, further comprises a polymerization initiator. Preferably said polymerization initiator is selected from photo-radical initiators, photo-acid generators or a combination of photo-radical initiator and photo-acid generator.

4. The composition of any one of preceding embodiments, further comprises a chemical compound containing at least two (meth)acryloyloxy groups.

preferably said at least two(meth)acryloyloxy groups are two or more acryloyloxy groups, methacryloyloxy groups or a combination of these, preferably the total amount of the chemical compound containing said at least two (meth)acryloyloxy groups based on the total amount of the alkaline soluble polymer is in the range from 5 wt. % to 1,000 wt. %, more preferably from 10 wt. % to 500 wt. %, even more preferably it is from 15 wt. % to 300 wt. %, preferably said chemical compound is a monomer having the molecular weight 2000 or less, more preferably in the range from 2000 to 50, even more preferably from 1000 to 100 preferably it is a poly acrylate monomer having at least three (meth)acryloyloxy groups, more preferably it is a poly acrylate monomer selected from one or more member of the group consisting of a poly acrylate monomer having three (meth)acryloyloxy groups, a poly acrylate monomer having four (meth)acryloyloxy groups, a poly acrylate monomer having five (meth)acryloyloxy groups, a poly acrylate monomer having six (meth)acryloyloxy groups, even more preferably it is a poly acrylate monomer having five (meth)acryloyloxy groups, a poly acrylate monomer having six (meth)acryloyloxy groups or a mixture of thereof,

preferably said poly acrylate monomer having three (meth)acryloyloxy groups is selected from one or more member of the group consisting of trimethylolpropane triacrylate, trimethylolpropaneethoxy triacrylate, trimethylolpropanepropoxy triacrylate, glycerinpropoxy triacrylate, pentaerythritol triacrylates;

preferably said poly acrylate monomer having four (meth)acryloyloxy groups is selected from one or more member of the group consisting of pentaerythritol tetraacrylates, ditrimethylolpropane tetraacrylate, pentaerythritolehoxy tetraacrylates;

preferably said poly acrylate monomer having five (meth)acryloyloxy groups is dipentaerythritol hexaacrylates, preferably said poly acrylate monomer having six (meth)acryloyloxy groups is dipentaerythritol pentaacrylate, the most preferably said chemical compound is dipentaerythritol hexaacrylates, dipentaerythritol pentaacrylate or a mixture of thereof.

5. The composition of any one of preceding embodiments, further comprises a surfactant.

preferably the total amount of the surfactant is in the range from 0.001 to 5 wt. %, more preferably from 0.01 to 4 wt. %, even more preferably from 0.05 to 3 wt. %, furthermore preferably from 0.1 to 1 wt. % based on the total solid contents of the composition.

6. The composition of any one of preceding embodiments, further comprises a solvent, preferably said solvent is selected from one or more of the members of the group consisting of ethylene glycol monoalkyl ethers, preferably selected from ethylene glycol monomethyl ether, ethylene glycol monoethyl ether, ethylene glycol monopropyl ether and ethylene glycol monobutyl ether; diethylene glycol dialkyl ethers, preferably selected from diethylene glycol dimethyl ether, diethylene glycol diethyl ether, diethylene glycol dipropyl ether and diethylene glycol dibutyl ether; ethylene glycol alkyl ether acetates, preferably selected from methyl cellosolve acetate and ethyl cellosolve acetate; propylene glycol monoalkyl ethers, preferably selected from propylene glycol monomethyl ether and propylene glycol monoethyl ether; propylene glycol alkyl ether acetates, preferably it is selected from PGMEA, propylene glycol monoethyl ether acetate and propylene glycol monopropyl ether acetate; aromatic hydrocarbons, preferably selected from benzene, toluene and xylene; ketones, preferably selected from methyl ethyl ketone, acetone, methyl amyl ketone, methyl isobutyl ketone and cyclohexanone; alcohols, preferably selected from ethanol, propanol, butanol, hexanol, cyclohexanol, ethylene glycol and glycerin; esters, preferably selected from ethyl lactate, ethyl 3-ethoxypropionate and methyl 3-methoxypropionate; and cyclic esters, preferably it is γ-butyrolactone, more preferably said solvent is a combination of propylene glycol alkyl ether acetates or esters, and cyclic esters that is preferably γ-butyrolactone, preferably the total amount of said solvent based on the total amount of the composition is in the range from 1 wt. % to 99 wt. %, preferably from 5 wt. % to 90 wt. %, even more preferably from 10 wt. % to 80 wt. %, furthermore preferably from 20 wt. % to 70 wt. %.

7. The composition of any one of preceding embodiments, further comprises another colorant different from the colorant of embodiment 1. preferably said another colorant is a 2^{nd} colorant selected from an organic colorant and/or an inorganic colorant, more preferably it is a black colorant selected from an organic black pigment and/or inorganic black pigment or a white colorant selected from an organic white pigment and/or inorganic white pigment, even more preferably it is a white colorant selected from an organic white pigment and/or inorganic white pigment, furthermore preferably it is an inorganic white colorant.

8. The composition of any one of preceding embodiments, further comprises at least one additive selected from one or more members of the group consisting of a developer dissolution accelerator, a scum remover, an adhesion enhancer, a polymerization inhibitor, an antifoaming agent, a surfactant, a photosensitizing enhancing agent, a crosslinking agent, a curing agent.

9. A method for fabricating a cured layer comprising at least the following steps;
(Xi) providing the composition of any one of embodiments 1 to 8 onto a layer or onto a substrate to form a coated layer; and
(Xii) baking a coated layer to obtain a cured layer.

Preferably the method further comprises one or more of the following steps after step (Xi) and before the step (Xii):
(Xiii) Applying a pre-baking (heat treatment) of the coating layer in order to dry the coated layer and reduce the residual amount of the solvent in the coated layer. Preferably said pre-baking process is carried out at a temperature of generally 50 to 150° C., preferably 90 to 120° C., in the case of a hot plate, for 10 to 300 seconds, preferably 30 to 120 seconds and in the case of a clean oven, for 1 to 30 minutes;
(Xiv) irradiating the coated layer with light (applying light irradiation), preferably with light having peak maximum wavelength in the range from 360 to 430 nm, preferably a patterning mask is used when light irradiation is carried out;
(Xv) applying post exposure baking process; and/or
(Xvi) applying developing process to form a patterned cured layer.

10. A layer obtained or obtainable from the method of embodiment 9.

11. A layer comprising at least;
i) a polymer (A) derived or derivable from an alkaline soluble polymer containing an ethylenic double bond;
preferably the solid acid value of the alkaline polymer is in the range from 30 to 160 mgKOH/g, more preferably from 50 to 150 mg KOH/g, even more preferably from 60 to 80 mg KOH/g,
preferably the weight-average molecular weight of said alkaline soluble polymer is in the range from 1,000 to 100,000, more preferably it is from 1,200 to 30,000, even more preferably it is from 3000 to 8000,
preferably said alkaline soluble polymer is selected from (meth)acrylate polymer, more preferably it is a methacrylate polymer, an acrylate polymer or a combination of thereof, even more preferably the polymer material is an acrylate polymer; and
ii) a colorant.

Preferably said layer is a patterned layer.

Preferably said colorant is a 1^{st} colorant selected from an organic colorant and/or an inorganic colorant, more preferably it is a black colorant selected from an organic black pigment and/or inorganic black pigment or a white colorant selected from an organic white pigment and/or inorganic white pigment, furthermore preferably it is a black colorant selected from an organic black pigment and/or inorganic black pigment, even more preferably it is a inorganic black pigment, particularly preferably said inorganic black pigment is zirconium nitride or a tinatnina oxide, which may be coated by a polymer and/or inorganic layer.

12. The layer of embodiment 10 or 11, wherein the Optical Density (OD) value of the layer at 10 μm layer thickness at light wavelength 460 nm is in the range from 1.0 to 3.0, at light wavelength 540 nm is in the range from 1.0 to 3.0, and/or at light wavelength 630 nm is in the range from 1.0 to 3.0.

13. The layer of any one of embodiments 10 to 12, wherein the reflection of the layer at 10 μm layer thickness at light wavelength 460 nm is in the range from 30 to 90%, at light wavelength 540 nm is in the range from 30 to 90% and/or at light wavelength 630 nm is in the range from 30 to 90%.

14. A light converting device comprising at least the layer of any one of embodiments 10 to 13. Preferably said light converting device further comprises a substrate.

15. An optical device comprising at least the layer of any one of embodiments 10 to 13 or a light converting device of embodiment 14.

16. Use of the composition of any one of embodiments 1 to 8, or the layer of any one of embodiments 10 to 13 in a fabrication process of a light converting device.

17. Use of the light converting device of embodiment 14 in a fabrication process of an optical device.

18. Method of fabricating an optical device comprising at least; providing the light converting device of embodiment 14 into an optical device.

### Technical Effects of the Invention

Present invention provides one or more of the following effects: enabling development with a low-concentration alkaline developer, preferably in a shorter development time and/or achieving both reactivity and storage stability of the composition, realizing high sensitivity of the composition lowering exposure energy and exposure time, improving structure of a patterned cured film (bank structure), especially, improving bottom side structure of a patterned cured film, realizing improved reflection and/or high optical density (OD) of the cured film, especially realizing improved reflection and/or high OD of the cured film having white and black pigments (grey colored bank).

The working examples below provide descriptions of the present invention, as well as an in-detail description of their fabrication. However, the present invention is not necessary to be limited to the working examples.

### WORKING EXAMPLES

### Working Example 1: Preparation of Bank Composition

The bank composition 1 is prepared with using the following materials.

TABLE 1

| | | | |
|---|---|---|---|
| Alkaline soluble polymer | Acryl polymer A | 75 | wt. parts |
| | Acryl polymer B | 25 | wt. parts |
| Chemical compound | A-DPH (Shin-Nakamura) | 100 | wt. parts |
| (Monomer) | | | |
| Photo-radical Initiator | NCI-831E (Adeka) | 3.0 | wt. parts |
| Photo-acid generator | Photosensitive sulfonium | 3.0 | wt. parts |
| | salt photoacid generator | | |
| | (San-Apro) | | |
| Surfactant | RS-72-A (DIC) | 0.9 | wt. parts |
| Colorant 1 | Black Pigment UB-1 | 0.8 | wt. parts |
| | (Mitsubishi Material | | |
| | Electronic Chemicals) | | |
| Colorant 2 | TiO2 particle dispersion 1 | 336 | wt. parts |
| | (Toyocolor) | | |
| Total solid contents | | 543.7 | wt. parts |
| (100%) | | | |
| Solvent | PGMEA | 664.5 | wt. parts |

| | |
|---|---|
| Total | 100% |

Acryl polymer A: acrylic randam polymer made from carbon acid monomer and monomer containing at least one aromatic ring group (Shin-Nakajima).

Acryl polymer B: 2-Propenoic acid, 2-methyl-, polymer with 2-hydroxyethyl 2-methyl-2-propenoate, 2-isocyanatoethyl 2-propenoate and methyl 2-methyl-2-propenoate (Natoco).

Here PGMEA solvent is added so that the composition contains 45 wt % of total solid contents and 55 wt % of solvent based on the total weight of the composition after adding the solvent.

### Working Examples 2-11: Preparation of Bank Compositions

The bank compositions 2-11 are prepared in the same manner as described in working example 1 above except for that the following materials as mentioned in table 2 are used instead of the materials used in working example 1. Here PGMEA solvent (not mentioned in the table 2) is added so that the composition contains 45 wt % of total solid contents and 55 wt % of solvent based on the total weight of the composition after adding the solvent as same to working example 1.

TABLE 2A

| | | W.E.1 | | | | | |
|---|---|---|---|---|---|---|---|
| | | (wt. parts) | W.E.2 | W.E.3 | W.E.4 | W.E.5 | W.E.6 |
| Chemical compound | A-DPH | 100 | 100 | 100 | 100 | 100 | 100 |
| (Monomer) | | | | | | | |
| Alkaline soluble | Acryl polymer A | 75 | 75 | 75 | 75 | 75 | 75 |
| polymer | Acryl polymer B | 25 | 25 | 25 | 25 | 25 | 25 |
| Surfactant | RS-72-A | 0.9 | 0.9 | 0.9 | 0.9 | 0.9 | 0.9 |
| Colorant 2 | TiO₂ particle dispersion 1 | 336 | — | — | — | — | — |
| (White pigment) | (Toyocolor) | | | | | | |
| | TiO₂ particle dispersion 2 | — | 336 | — | — | — | — |
| | (Toyocolor) | | | | | | |
| | TiO₂ particle dispersion 3 | — | — | 336 | — | — | — |
| | (Toyocolor) | | | | | | |
| | TiO₂ particle dispersion 4 | — | — | — | 336 | — | — |
| | (Toyocolor) | | | | | | |
| | TiO₂ particle dispersion 5 | — | — | — | — | 336 | — |
| | (Toyocolor) | | | | | | |
| | TiO₂ particle dispersion 6 | — | — | — | — | — | 336 |
| | (Toyocolor) | | | | | | |
| Colorant 1 | Black pigment | 0.8 | 0.8 | 0.9 | 1.4 | 1.5 | 1.8 |
| | UB-1 | | | | | | |
| Photo-radical initiator | NCI-831E | 3 | 3 | 3 | 3 | 3 | 3 |
| Photo-acid generator | Photosensitive sulfonium salt | 3 | 3 | 3 | 3 | 3 | 3 |
| | photoacid generator | | | | | | |
| | (San-Apro) | | | | | | |

TABLE 2B

| | | W.E.7 | W.E.8 | W.E.9 | W.E.10 | W.E.11 |
|---|---|---|---|---|---|---|
| Chemical compound | A-DPH | 100 | 100 | 100 | 100 | 100 |
| (Monomer) | | | | | | |
| Alkaline soluble | Acryl polymer A | 75 | 75 | 75 | 75 | 75 |
| polymer | Acryl polymer B | 25 | 25 | 25 | 25 | 25 |
| Surfactant | RS-72-A | 0.9 | 0.9 | 0.9 | 0.9 | 0.9 |
| Colorant 2 | TiO2 particle dispersion 7 | — | 336 | 336 | 336 | 336 |
| (White pigment) | (Toyocolor) | | | | | |
| | TiO2 particle dispersion 8 | 336 | — | — | — | — |
| | (Toyocolor) | | | | | |
| | TiO2 particle dispersion | — | 100 | — | — | — |
| | (Sakai chemical industry) | | | | | |
| | TiO2 particle dispersion A | — | — | 100 | — | — |
| | (Tokushiki) | | | | | |
| | TiO2 particle dispersion B | — | — | — | 100 | — |
| | (Tokushiki) | | | | | |
| | TiO2 particle dispersion C | — | — | — | — | 100 |
| | (Tokushiki) | | | | | |
| Colorant 1 | Black pigment | 1.8 | 1.5 | 1.5 | 1.5 | 1.5 |
| | UB-1 | | | | | |
| Photo-radical initiator | NCI-831E | 3 | 3 | 3 | 3 | 3 |
| Photo-acid generator | Photosensitive sulfonium | 3 | 3 | 3 | 3 | 3 |
| | salt photoacid generator | | | | | |
| | (San-Apro) | | | | | |

### Working Example 12: Fabrication of Cured Films (Cured Compositions)

For OD and reflection measurements of samples, samples 1 to 11 are fabricated by using the compositions from W.E. 1 to W.E. 11.

Firstly, obtained bank compositions from W.E.1 to W.E.11 are each separately coated onto a grass substrate by spin coater (MS-A100, MIKASA). Then coated glass substrates 1 to 11 are pre-baked on the hot-plate (HHP-411 V, AS ONE) at 100° C. for 90 sec. to obtain 15 um average layer thickness of pre-baked composition coated on the substrate.

Then the whole surface of the samples is exposured to light by ghi-line exposure machine for photoliso graphy (NES2W-ghi06, Nikon) at 120 mJ/cm² without using any pattern mask and Post exposure baking process is applied for the samples with using the hot-plate (HHP-411 V, AS ONE) at 120° C. for 90 sec.

Then, post exposure baked samples 1 to 11 are developed by 0.03 wt % KOHaq used as a developer for 180 sec.

Obtained samples are baked by oven (DP-200 Yamato) at 230° C. for 30 min to promote curing.

Then baked samples are cooled down to the room temperature. Finally, samples 1 to 11 are obtained.

### Working Example 13: Measurement of Optical Density (OD) Values

The transmission spectrum of the obtained samples 1 to 11 from working example 12 is measured by spectrophotometric colorimeter (CM-5 Konica Minolta). And the OD values at 460, 540, 630 nm of each samples are calculated.

### Working Example 14: Measurement of Reflectance of the Samples

The reflection spectrum of each obtained samples is measured by spectrophotometric colorimeter (CM-5 Konica Minolta). And the reflectance at 460, 540, 630 nm of each samples is separately calculated.

Table 3 shows the results of W.E. 13 and W.E.14.

### Working Example 15: Evaluation of Developing Properties

### 1. Preparation of Evaluation Samples 1 to 11

Evaluation samples 1 to 11 are fabricated by using the compositions from W.E. 1 to W.E. 11.

Firstly, obtained bank compositions from W.E.1 to W.E.11 are each separately coated onto a grass substrate by spin coater (MS-A100, MIKASA). Then coated glass substrates 1 to 11 are pre-baked on the hot-plate (HHP-411 V, AS ONE) at 100° C. for 90 sec. to obtain 15 um average layer thickness of pre-baked composition coated on the substrate.

Then the whole surface of the samples is exposured to light by ghi-line exposure machine for photoliso graphy (NES2W-ghi06, Nikon) at 120 mJ/cm² with using a patterned mask to make 150*150 μm hole patterns after developing process. Then, Post exposure baking process is applied for the samples with using the hot-plate (HHP-411 V, AS ONE) at 120° C. for 90 sec.

Then, the baked samples 1 to 11 are developed by 0.03 wt % KOHaq used as a developer for 150 sec to make 150*150 μm hole patterns.

Obtained samples are baked by oven (DP-200 Yamato) at 230° C. for 30 min to promote curing.

Then baked samples are cooled down to the room temperature. Finally, samples 1 to 11 are obtained.

### 2. Evaluation of Developing Property of the Obtained Samples

Developing/patterning property of the obtained evaluation samples 1A to 11A is evaluated with using optical microscope (MX61A, OLYMPUS).

Especially, obtained samples 1 to 11 are evaluated by the microscope if there is any development residue in the unexposed area of each samples.

Obtained results are indicated in table 3.

Here result “A” means “no development residue in the unexposed area” and no pattern defects.”

Result “B”: there are development residue in the unexposed area and/or any pattern defects observed.

TABLE 3

| | W.E.1 | W.E.2 | W.E.3 | W.E.4 | W.E.5 | W.E.6 |
|---|---|---|---|---|---|---|
| | Sample 1 | Sample 2 | Sample 3 | Sample 4 | Sample 5 | Sample 6 |
| OD at 460 nm | 1.6 | 1.8 | 1.8 | 2.1 | 1.7 | 1.4 |
| OD at 540 nm | 1.2 | 1.4 | 1.4 | 1.7 | 1.4 | 1.2 |
| OD at 630 nm | 1.0 | 1.2 | 1.2 | 1.6 | 1.3 | 1.1 |
| Reflectance at 460 nm (%) | 52 | 44 | 49 | 45 | 46 | 46 |
| Reflectance at 540 nm (%) | 57 | 48 | 53 | 47 | 47 | 47 |
| Reflectance at 630 nm (%) | 55 | 46 | 50 | 44 | 44 | 43 |
| Developing property | A | A | A | A | A | A |

| | W.E.7 | W.E.8 | W.E.9 | W.E.10 | W.E.11 |
|---|---|---|---|---|---|
| | Sample 7 | Sample 8 | Sample 9 | Sample 10 | Sample 11 |
| OD at 460 nm | 1.5 | 2.5 | 2.5 | 2.2 | 1.9 |
| OD at 540 nm | 1.2 | 2.1 | 2.1 | 1.8 | 1.7 |
| OD at 630 nm | 1.1 | 1.9 | 1.9 | 1.6 | 1.6 |
| Reflectance at 460 nm (%) | 51 | 54 | 47 | 51 | 40 |
| Reflectance at 540 nm (%) | 53 | 53 | 48 | 50 | 48 |
| Reflectance at 630 nm (%) | 49 | 49 | 45 | 46 | 55 |
| Developing property | A | A | A | A | A |

1. A composition comprising:
i) an alkaline soluble polymer containing an ethylenic double bond; and
ii) a first colorant,
wherein the composition is a photocurable composition that does not include any polysiloxane component.

2. The composition of claim 1, wherein the alkaline soluble polymer has a solid acid value in the range from 30 to 160 mgKOH/g.

3. The composition of claim 1, which further comprises a thiol containing polyfunctional chemical compound that includes a pentaerythritol structure.

4. The composition of claim 3, wherein the thiol containing polyfunctional chemical compound is represented by chemical formula (I^{x}) 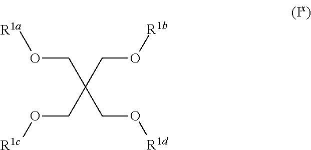
wherein
R^{1a}, R^{1b}, R^{1c} and R^{1d} are, independently of each other, selected from the group consisting of a hydrogen atom, an alkyl chain having 1 to 10 carbon atoms, a cyclo group having 3 to 10 carbon atoms, a cyclo-alkyl group having 4 to 10 carbon atoms, an aryl group having 3 to 10 carbon atoms and an alkoxy group having 1 to 10 carbon atoms, in which at least one H atom is replaced with a SH group, wherein one or more non-adjacent CH₂ groups is optionally replaced by an oxygen atom, C=O, C=S, C=Se, C═NH, SiH₂, SO, SO₂, OS, or CONH, wherein one or more H atoms is optionally replaced by D, F, Cl, Br, I, CN or NO₂, wherein at least one of R^{1a}, R^{1b}, R^{1c} and R^{1d} is not a hydrogen atom.

5. The composition of claim 1, further comprising a polymerization initiator.

6. The composition of claim 1, further comprising a chemical compound that includes at least two (meth)acryloyloxy groups.

7. The composition of claim 1, further comprising a surfactant.

8. The composition of claim 1, further comprising a solvent.

9. The composition of claim 1, further comprising a second colorant different from the first colorant.

10. The composition of claim 1, further comprising at least one additive selected from the group consisting of a developer dissolution accelerator, a scum remover, an adhesion enhancer, a polymerization inhibitor, an antifoaming agent, a surfactant, a photosensitizing enhancing agent, a crosslinking agent, and a curing agent.

11. A method for fabricating a cured layer comprising at least the following steps:
(Xi) providing the composition of claim 1 onto a substrate to form a coated layer; and
(Xii) baking the coated layer to obtain a cured layer.

12. The method of claim 11, further comprising one or more of the following steps after step (Xi) and before the step (Xii):
(Xiii) applying a pre-baking of the coating layer in order to dry the coated layer and reduce the residual amount of the solvent in the coated layer;
(Xiv) irradiating the coated layer with light;
(Xv) applying a post exposure baking process; and
(Xvi) applying a developing process to form a patterned cured layer.

13. A layer comprising:
i) a polymer (A) derived or derivable from an alkaline soluble polymer that includes an ethylenic double bond; and
ii) a colorant.

14. The layer of claim 13, wherein the alkaline polymer has a solid acid value in the range from 30 to 160 mgKOH/g.

15. The layer of claim 13, wherein the layer has an optical density (OD) value at 10 μm layer thickness at light wavelength 460 nm in the range from 1.0 to 3.0, at light wavelength 540 nm in the range from 1.0 to 3.0, and/or at light wavelength 630 nm in the range from 1.0 to 3.0.

16. The layer of claim 13, wherein the layer has a reflection at 10 μm thickness at light wavelength 460 nm in the range from 30 to 90%, at light wavelength 540 nm in the range from 30 to 90% and/or at light wavelength 630 nm in the range from 30 to 90%.

17. A light converting device comprising at least the layer of claim 13.

18. An optical device comprising at least the layer of claim 13.
